(19) United States
(12) Patent Application Publication
(10) Pub. No.: US 2021/0210515 A1
(43) Pub. Date: Jul. 8, 2021

(54) ARRAY SUBSTRATE, METHOD FOR MANUFACTURING THEREOF, DISPLAY PANEL AND DISPLAY DEVICE

(71) Applicant: BOE TECHNOLOGY GROUP CO., LTD., Beijing (CN)

(72) Inventors: Feng ZHANG, Beijing (CN); Wenqu LIU, Beijing (CN); Zhijun LV, Beijing (CN); Liwen DONG, Beijing (CN); Shizheng ZHANG, Beijing (CN); Ning DANG, Beijing (CN)

(73) Assignee: BOE TECHNOLOGY GROUP CO., LTD., Beijing (CN)

(21) Appl. No.: 16/069,353

(22) PCT Filed: Jan. 4, 2018
(86) PCT No.: PCT/CN2018/071375

§ 371 Date: Jul. 11, 2018

(30) Foreign Application Priority Data
May 16, 2017 (CN) 201710344017.2

(51) Int. Cl. H01L 27/12; H01L 27/32; H01L 51/52; H01L 51/56

(52) U.S. Cl. CPC H01L 27/1218; H01L 27/1262; H01L 51/56; H01L 51/5206; H01L 51/5253; H01L 27/3246

(57) ABSTRACT

An array substrate, a method for manufacturing the same, a display panel and a display device are disclosed. The array substrate includes: a substrate, and a planarization layer and a pixel definition layer sequentially disposed on the substrate, a protrusion is disposed on the planarization layer, the pixel definition layer is provided with an opening, and the protrusion is disposed in a region defined by the opening. The method for manufacturing the array substrate includes: forming a planarization layer on which a protrusion is disposed; forming a pixel definition layer, the pixel definition layer is provided with an opening, and the protrusion is disposed in a region defined by the opening.

### CROSS-REFERENCE OF RELATED APPLICATION

The present application claims the priority of Chinese patent application No. 201710344017.2 filed on May 16, 2017, the disclosure of which is hereby incorporated by reference herein in its entirety.

### TECHNICAL FIELD

Embodiments of the present disclosure relate to an array substrate, a method for manufacturing the same, a display panel and a display device.

### BACKGROUND

With the continuous development of science and technology, flat panel display devices carrying visual information have occupied an increasingly important position in people's life. The flat panel display devices include liquid crystal (LCD) display devices and organic light emitting diode (OLED) display devices. The active matrix organic light emitting diode (AMOLED) display device is a category of the OLED display device, and typically comprises a thin film transistor (TFT) and an OLED unit.

At present, the existing manufacturing method of AMOLED back plate comprises a process of manufacturing a spacer. However, during the process of manufacturing the spacer, organic film residues may be left in a pixel definition region, and the light emission characteristics of the light emission material after vapor deposition would be affected, or even the defects would be caused, so that the detect-free ratio is largely reduced.

### SUMMARY

An embodiment of the present disclosure discloses an array substrate, comprising: a substrate; a planarization layer and a pixel definition layer sequentially disposed on the substrate, wherein a protrusion is disposed on the planarization layer, the pixel definition layer is provided with an opening, and the protrusion is disposed in a region defined by the opening.

In at least some embodiments, the array substrate further comprises an anode, wherein the anode is disposed on the protrusion.

In at least some embodiments, the array substrate further comprises a spacer, wherein the spacer is disposed on the pixel definition layer.

In at least some embodiments, a top surface of the pixel definition layer is higher than a top surface of the protrusion, relative to a plane of the substrate.

In at least some embodiments, a thickness of the protrusion ranges from 1 μm to 3 μm, and a thickness of the pixel definition layer ranges from 1.4 μm to 3.6 μm.

In at least some embodiments, a top surface of the pixel definition layer is higher than a top surface of the anode, relative to the plane of the substrate.

In at least some embodiments, a height difference between the top surface of the pixel definition layer and the top surface of the anode ranges from 0.2 μm to 0.4 μm.

Another embodiment of the present disclosure discloses a method for manufacturing an array substrate, comprising: forming a planarization layer on which a protrusion is disposed; and forming a pixel definition layer, wherein the pixel definition layer is provided with an opening, and the protrusion is disposed in a region defined by the opening.

In at least some embodiments, the method further comprises: forming an anode on the protrusion.

In at least some embodiments, the method further comprises: forming a spacer on the pixel definition layer.

In at least some embodiments, both the planarization layer and the pixel definition layer are formed on the substrate, and a top surface of the pixel definition layer is higher than a top surface of the protrusion, relative to a plane of the substrate.

In at least some embodiments, a thickness of the protrusion ranges from 1 μm to 3 μm, and a thickness of the pixel definition layer ranges from 1.4 μm to 3.6 μm.

In at least some embodiments, both the planarization layer and the pixel definition layer are formed on the substrate, and a top surface of the pixel definition layer is higher than a top surface of the anode, relative to the plane of the substrate.

In at least some embodiments, a height difference between the top surface of the pixel definition layer and the top surface of the anode ranges from 0.2 μm to 0.4 μm.

In at least some embodiments, the forming a planarization layer on which a protrusion is disposed comprises: forming a planarization layer; and exposing the planarization layer with a dual-tone or halftone mask and developing, wherein a region of the planarization film where a via hole is to be formed in the planarization layer is a full exposure region; a region where an opening is to be formed is an non-exposure region, and the protrusion is formed in non-exposure region; the remaining region is a partial exposure region, in which the planarization layer is to be formed.

In at least some embodiments, the planarization layer and the protrusion are made of a photosensitive material.

Still another embodiment of the present disclosure discloses a display panel, comprising the afore-mentioned array substrate.

Yet another embodiment of the present disclosure discloses a display device, comprising the afore-mentioned display panel.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 schematically illustrates an array substrate according to the present disclosure;

FIG. 2 schematically illustrates an array substrate according to an embodiment of the present disclosure;

FIG. 3 schematically illustrates a flow diagram of a method for manufacturing an array substrate according to an embodiment of the present disclosure;

FIG. 4 schematically illustrates a diagram after a step of forming a functional layer according to an embodiment of the present disclosure;

FIG. 5 schematically illustrates a diagram after a step of coating a planarization layer according to an embodiment of the present disclosure;

FIG. 6 schematically illustrates a diagram after a step of exposing and developing the planarization layer according to an embodiment of the present disclosure;

FIG. 7 schematically illustrates a diagram after a step of forming an anode according to an embodiment of the present disclosure;

FIG. 8 schematically illustrates a diagram after a step of forming a pixel definition layer according to an embodiment of the present disclosure;

FIG. 9 schematically illustrates an array substrate according to another embodiment of the present disclosure;

FIG. 10 schematically illustrates a mask according to an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present disclosure, are not intended to indicate any sequence, amount or importance, but distinguish various components. The terms “comprises,” “comprising,” “includes,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

FIG. 1 schematically illustrates an array substrate according to the present disclosure. As illustrated in FIG. 1, the array substrate (also called AMOLED back plate) comprises: a substrate 10, a planarization layer (PLN) 30 formed on the substrate 10, an anode 40 formed on the planarization layer 30, a pixel definition layer (PDL) 50 and a spacer 60 formed on the pixel definition layer 50. The pixel definition layer 50 is provided with an opening. An opening region is also called as a pixel definition region, which is configured to expose the anode, such that the anode can connect with OLED functional material and realize light emission function.

Due to the existence of a larger step difference D as illustrated in FIG. 1, the organic film residues left in the pixel definition region during the process of manufacturing the spacer. The step difference D results in organic film residues in the pixel definition region, which not only affects the light emission characteristics of the light emission material after vapor deposition, but also causes the defects of the array substrate, thereby reducing the defect-free ratio.

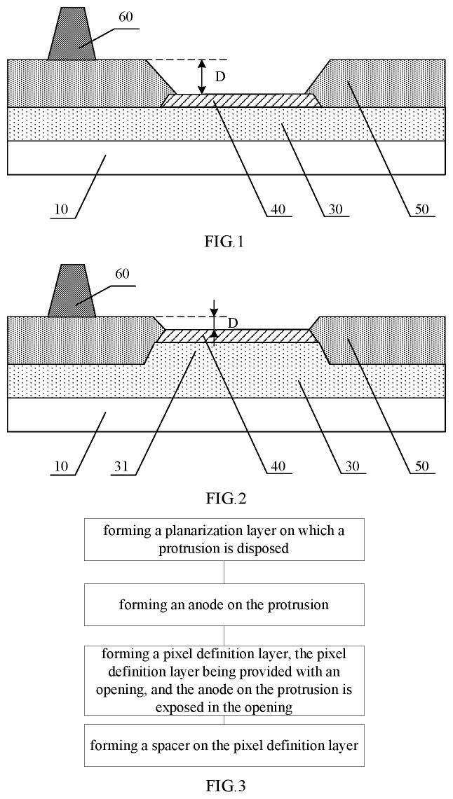

To overcome the above problems, an embodiment of the present disclosure provides an array substrate. FIG. 2 schematically illustrates an array substrate according to an embodiment of the present disclosure. As illustrated in FIG. 2, the array substrate comprises: a substrate 10; a planarization layer 30 and a pixel definition layer 50 sequentially disposed on the substrate 10; a protrusion 31 is disposed on the planarization layer 30, an opening is formed in the pixel definition layer 50, and the protrusion 31 is disposed in a region defined by the opening.

In the array substrate provided in embodiments of the present disclosure, the protrusion 31 is disposed on the planarization layer 30, and a top surface of the pixel definition layer 50 is higher than a top surface of the protrusion 31. For example, a thickness of the protrusion 31 ranges from 1 μm to 3 μm, a thickness of the pixel definition layer 50 ranges from 1.4 μm to 3.6 μm, the height difference between the top surface of the pixel definition layer 50 and the top surface of the protrusion 31 ranges from 0.4 μm to 0.6 μm. Because the protrusion is disposed on the planarization layer, the step difference between the planarization layer and the pixel definition layer is reduced, the organic film residues in the opening region during the patterning process of the spacer is avoided, and the light emission characteristics and defect-free ratio of the array substrate are increased.

In at least some embodiments, the array substrate further comprises an anode 40 disposed on the protrusion 31 of the planarization layer 30. For example, the anode 40 overlays and is in contact with the protrusion 31, the top surface of the pixel definition layer 50 is higher than a top surface of the anode 40 relative to the plane of the substrate 10.

In at least some embodiments, the array substrate further comprises a spacer 60 disposed on the pixel definition layer 50.

Relative to the plane of the substrate, the top surface of the pixel definition layer is higher than the top surface of the protrusion, the thickness of the protrusion ranges from 1 μm to 3 μm, the thickness of the pixel definition layer ranges from 1.4 μm to 3.6 μm; the protrusion is disposed in the region defined by the opening of the pixel definition layer, so that the top surface of the pixel definition layer is higher than the top surface of the anode, and the height difference between the top surface of the pixel definition layer and the top surface of the anode ranges from 0.2 μm to 0.4 μm.

In the array substrate provided in embodiments of the present disclosure, the protrusion is disposes on the planarization layer and the anode is disposed on the protrusion, the step difference between the pixel definition layer and the anode is effectively reduced. Due to the smaller step difference, the organic film residues in the opening region generated in the patterning process of the spacer can be avoided, and the light emission characteristics and defect-free ratio of the array substrate can be both increased.

In at least some embodiments, the array substrate further comprises a functional layer, the functional layer is disposed on the substrate, and the planarization layer is disposed on the functional layer. Other layers may also be disposed between the layers such as the planarization layer, the anode, the pixel definition layer and the spacer; the anode may be disposed on the planarization layer or may be disposed on other layers, and which is not specifically limited in embodiments of the present disclosure.

As illustrated in FIG. 2, the embodiment of the present disclosure further provides a method for manufacturing an array substrate, which comprises:

forming a planarization layer 30 on which a protrusion 31 is disposed; and

forming a pixel definition layer 50, the pixel definition layer 50 being provided with an opening, wherein the protrusion 31 is disposed in a region defined by the opening.

By disposing the protrusion 31 on the planarization layer 30, a top surface of the pixel definition layer 50 is higher than a top surface of the protrusion 31. For example, a thickness of the protrusion 31 ranges from 1 μm to 3 μm, a thickness of the pixel definition layer 50 ranges from 1.4 μm to 3.6 μm, a height difference between the top surface of the pixel definition layer 50 and the top surface of the protrusion 31 ranges from 0.4 μm to 0.6 μm. Because the protrusion is disposed on the planarization layer, the step difference between the planarization layer and the pixel definition layer is reduced, the organic film residues in the opening region during the patterning process of the spacer is avoided, and the light emission characteristics and defect-free ratio of the array substrate are increased.

In at least some embodiments, the above method further comprises: forming an anode 40 on the protrusion 31. For example, the anode 40 overlays and is in contact with the protrusion 31.

In at least some embodiments, the above method further comprises: forming a spacer 60 on the pixel definition layer 50.

FIG. 3 schematically illustrates a flow diagram of a method for manufacturing an array substrate according to another embodiment of the present disclosure. As illustrated in FIG. 3, the method for manufacturing an array substrate comprises:

forming a planarization layer on which a protrusion is disposed;

forming an anode on the protrusion;

forming a pixel definition layer, the pixel definition layer being provided with an opening, and the anode on the protrusion is exposed in the opening; and

forming a spacer on the pixel definition layer.

The top surface of the pixel definition layer is higher than the top surface of the protrusion, the thickness of the protrusion ranges from 1 μm to 3 μm, the thickness of the pixel definition layer ranges from 1.4 μm to 3.6 μm, the protrusion is disposed in the region defined by the opening of the pixel definition layer, the top surface of the pixel definition layer is higher than the top surface of the anode, and the height difference between the top surface of the pixel definition layer and the top surface of the anode ranges from 0.2 μm to 0.4 μm.

In at least some embodiments, the step of forming a planarization layer on which a protrusion is disposed comprises: forming the planarization layer with the protrusion by a single patterning process.

In at least some embodiments, a planarization film is made of a photosensitive material, in this case, the step of forming the planarization layer with the protrusion by a single patterning process comprises: forming the planarization film; exposing and developing the planarization film with a dual-tone or halftone mask, wherein a region of the planarization film where a via hole is to be formed in the planarization layer is a full exposure region; a region where an opening is to be formed (i.e., the opening region) is an non-exposure region, and the protrusion is formed in the non-exposure region; the remaining region is a partial exposure region, in which the planarization layer is to be formed. In the present embodiment, the planarization layer and the protrusion are made of the planarization film, that is, both of them is made of a photosensitive material, so they can be integrally formed, without coating any other photoresists on the planarization film. As illustrated in FIG. 2, the planarization layer 30 and the protrusion 31 are integrally formed.

In at least some embodiments, the planarization layer and the protrusion are made of two different materials, in this case, the step of forming the planarization layer with the protrusion by a single patterning process comprises:

forming a planarization film;

forming a photoresist layer on the planarization film;

exposing and developing the photoresist layer with a dual-tone or halftone mask, for example, as illustrated in FIG. 10, the mask 6 comprises a completely light-transmissive region 61, a light-blocking region 62 and a partially light-transmissive region 63, so that a full-exposure region, a non-exposure region and a partial-exposure region are formed in the photoresist. The full-exposure region corresponds to the position where a via hole is to be formed, that is, a via hole passed through the planarization film is to be formed; the non-exposure region corresponds to the opening region, in which a protrusion is formed, and the remaining region is the partially exposed region, in which the planarization layer is formed;

etching the planarization film in the completely exposed region to form the via hole;

ashing the photoresist to expose the planarization film in the partial-exposure region, and etching part of the planarization film in the partial-exposure region to form the planarization layer; and

removing remaining photoresist to form the protrusion.

In the method of manufacturing the array substrate provided in the embodiments of the present disclosure, the protrusion is formed on the planarization layer and the anode is formed on the protrusion, the height difference between the top surface of the pixel definition layer and the top surface of the anode ranges from 0.2 μm to 0.4 μm. Due to the smaller step difference, the organic film residues in the opening region during the patterning process of the spacer can be avoided, and the light emission characteristics and defect-free ratio of the array substrate can be both increased.

In at least some embodiments, before forming the planarization layer on which the protrusion is disposed, the method further comprises: providing a substrate, and forming the planarization layer and the pixel definition layer on the substrate.

In at least some embodiments, before forming the planarization layer on which the protrusion is disposed, the method further comprises: forming a functional layer on the substrate. The planarization layer may be formed on the functional layer after the functional layer is formed. Between any two sequential steps illustrated in FIG. 3, other layers may also be formed. The step of forming the anode may also be disposed between other two steps, and which is not specifically limited in embodiments of the present disclosure.

In embodiments of the present disclosure, the protrusion and the planarization layer may be formed by one patterning process, and may also be formed separately by two patterning processes, that is, the planarization layer is formed first and then a plurality of protrusions are formed on the planarization layer. The material of the protrusion may be the same as or different from the material of the planarization layer.

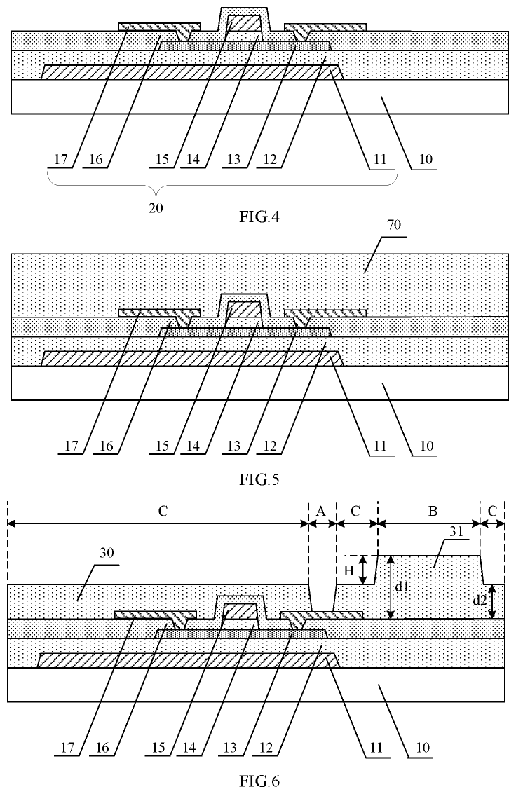

FIGS. 4 to 8 schematically illustrate steps of manufacturing the array substrate according to an embodiment of the present disclosure; the array substrate (for example, an AMOLED back plate) has a top-gate structure. The term “patterning process” in the present embodiment comprises the steps of depositing a film layer, coating a photoresist, exposing with a mask, developing, etching, peeling a photoresist, and so on. The deposition process includes but not limit to sputtering, evaporation and chemical vapor deposition, and so on. The coating process includes but not limit to physical or chemical coating process. The etching process includes but not limit to reactive ion etching (RIE) method, and so on.

According to the present embodiment, a method for manufacturing a top-gate array substrate comprises:

First, for example, forming a functional layer 20 on the substrate 10 by several patterning processes, as illustrated in FIG. 4. In at least some embodiments, the functional layer 20 comprises a light shielding layer 11, a buffer layer 12, an active layer 13, a gate insulation layer 14, a gate electrode 15, a passivation layer 16 and a source-drain electrode 17. The active layer 13 may be a low temperature polysilicon (LTPS) active layer or may also be an oxide active layer, and the oxide may be indium gallium zinc oxide (IGZO) or indium tin zinc oxide (ITZO), which is not specifically limited hereto.

Next, forming a planarization layer with a pattern of protrusion by a patterning process using a dual tone or halftone mask on the substrate which has the functional layer disposed thereon, and the pattern of protrusion is disposed in an opening region which is to be formed in a pixel defining layer.

In at least some embodiments, a step of forming the planarization layer with the pattern of protrusion comprises:

coating a planarization film 70 on the functional layer, as illustrated in FIG. 5. For example, the planarization film is made of photosensitive material, such as an organic transparent resin, and its thickness ranges from 2.5 μm to 5 μm.

exposing the planarization film 70 by using a dual-tone or halftone mask and developing. As an example, using the mask 6 illustrated in FIG. 10, which comprises a completely light-transmissive region 61, a light-blocking region 62 and a partially light-transmissive region 63. A position of a via hole through which the anode is connected with the source-drain electrode is in a full-exposure region A, and the full-exposure region A corresponds to the completely light-transmissive region 61; the via hole is formed by removing the planarization film in the full-exposure region A, and therefore no planarization film remains in full-exposure region A. The opening region to be formed in the pixel defining layer is to be formed in a non-exposure region B, which corresponds to the light-blocking region 62; the planarization film in the non-exposure region B has a first thickness d1, and a protrusion 31 is formed in the non-exposure region B; the remaining region is a partial-exposure region C, which corresponds to the partially light-transmissive region 63; the planarization film in the partial-exposure region C has a second thickness d2, and a planarization layer 30 is formed in the partial-exposure region C. The first thickness d1 is greater than the second thickness d2, as illustrated in FIG. 6. For example, the second thickness d2 ranges from 1.5 μm to 2 μm, and the first thickness d1 ranges from 2.5 μm to 5 μm, so that the thickness of the pattern of protrusion or the height H of the pattern of protrusion relative to the top surface of planarization layer 30 ranges from 1 μm to 3 μm.

After that, forming an anode by a patterning process on the substrate on which the planarization layer is formed. For example, forming the anode comprises: depositing a transparent electrically conductive film on the planarization layer; coating a photoresist on the transparent electrically conductive film; exposing the photoresist with a single tone mask and developing, so as to form a non-exposure region at the position where the anode is to be formed and a full-exposure region at remaining position, the non-exposure region has the photoresist, while the full-exposure region has no photoresist; etching the transparent electrically conductive film in the full-exposure region, and peeling the remaining photoresist, so as to form the anode 40. The anode 40 is disposed on the protrusion 41, and the anode 40 is connected with the drain electrode of the source-drain electrode 17 through the via hole in the planarization layer, as illustrated in FIG. 7. The transparent electrically conductive film may be made of indium tin oxide (ITO), indium zinc oxide (IZO), or indium tin oxide/silver/indium tin oxide (ITO/Ag/ITO) composite film with a thickness of 0.1 μm to 0.4 μm.

Finally, forming a pixel definition layer by a patterning process on the substrate on which the before-mentioned patterns are formed. In at least some embodiments, forming the pixel definition layer comprises: coating a pixel definition film on the substrate; exposing the pixel definition film with a single tone mask and developing; forming a pattern of pixel definition layer 50, the pixel definition layer 50 has a plurality of openings which are configured to define a plurality of pixel regions, the openings may expose the anode 40 on the protrusion 31, as illustrated in FIG. 8. For example, the pixel definition film is made of polymide, acrylic or polyethylene terephthalate, and its thickness ranges from 1.4 μm to 3.6 μm. In real implementation, the thickness of the pixel definition film may be set according to the height of the protrusion, in order to make the thickness of the pixel definition layer be greater than the height of protrusion by 0.4 μm to 0.6 μm. As a result, the top surface of the pixel definition layer is higher than the top surface of the protrusion, and the height difference D between the top surface of the pixel definition layer and the top surface of the anode rages from 0.2 μm to 0.4 μm. In at least some embodiments, the above method further comprises a step of forming a spacer on the pixel definition layer.

It can be seen from the above manufacturing method that the pattern of protrusion is formed by a pattern process, and the step difference between the pixel definition layer and the anode is only 0.2 to 0.4 μm. Due to the smaller step difference, the organic film in the opening region can be completely etched off without any residues in the subsequent patterning process of manufacturing the spacer, and therefore no residues left in the opening region. Thus, the problem that there is the organic film residues remained in the opening region in the existing manufacturing process of the spacer of the array substrate can be solved, the light emission characteristics and defect-free ratio of the array substrate can be both increased. Additionally, compared with the existing manufacturing process, only the conventional mask is replaced with a halftone mask in the patterning process of manufacturing the planarization layer, so it is not necessary to make much modification to the existing manufacturing process.

In at least some embodiments, the process of manufacturing the functional layer may adopt conventional processes, for example, a light shielding layer 11 is formed on the substrate by a first patterning process; a buffer layer 12 and an active layer 13 are formed by a second patterning process; a gate insulation layer 14 and a gate electrode 15 are formed by a third patterning process; a passivation layer 16 with via holes are formed by a fourth patterning process; a source-drain electrode 17 is formed by a fifth patterning process.

The embodiment of the present disclosure further provides a top-gate array substrate, as illustrated in FIG. 8, which comprises:

a substrate 10; a light shielding layer 11 disposed on the substrate 10; a buffer layer 12 overlying the light shielding layer 11; an active layer 13 disposed on the buffer layer 12; a gate insulation layer 14 and a gate electrode 15 both disposed on the active layer 13; a passivation layer 16 overlying both the gate insulation layer 14 and the gate electrode 15; a source-drain electrode 17 disposed on the passivation layer 16; a planarization layer 30 overlying the source-drain electrode 17, wherein a protrusion 31 is disposed on the planarization layer 30 and has a thickness from 1 μm to 3 μm; an anode 40 disposed on the protrusion 31, the anode 40 is connected with a drain of the source-drain electrode 17 through a via hole in the planarization layer; a pixel definition layer 50 disposed on the anode 40, wherein the pixel definition layer 50 is provided with an opening, the protrusion 31 is disposed in a region defined by the opening, the opening is configured to expose the anode 40, an top surface of the pixel definition layer 50 is higher than the top surface of the anode 40, and a height difference between the top surface of the pixel definition layer 50 and the top surface of the anode 40 ranges from 0.2 μm to 0.4 μm.

In at least some embodiments, the protrusion is formed by a single patterning process using a halftone mask. For example, the spacer is further disposed on the pixel definition layer. The active layer may be a low temperature polysilicon active layer or may be an oxide active layer.

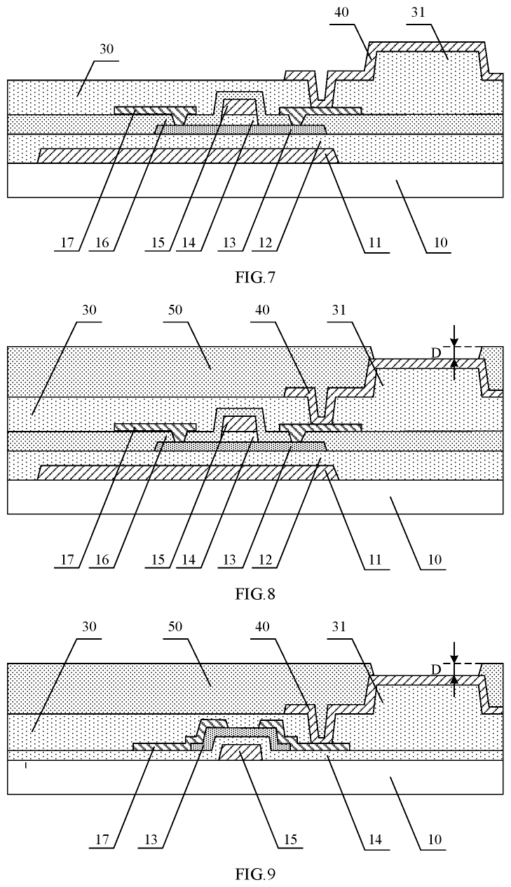

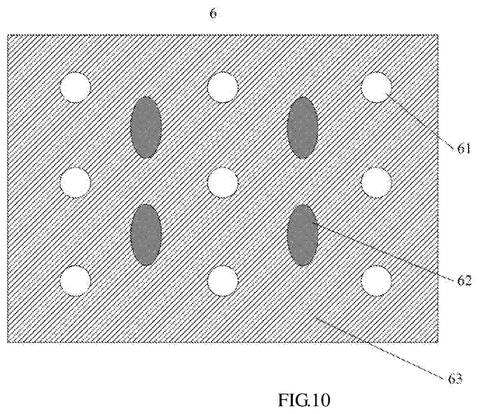

FIG. 9 schematically illustrates an array substrate according to another embodiment of the present disclosure which has a bottom-gate structure. A method for manufacturing the bottom-gate array substrate in the present embodiment comprises:

Firstly, forming a functional layer on the substrate 10 by several patterning processes, the functional layer comprises a gate electrode 15, a gate insulation layer 14, an active layer 13 and a source-drain electrode 17. The active layer 13 may be a low temperature polysilicon (LTPS) active layer or may also be an oxide active layer, and the oxide may be indium gallium zinc oxide (IGZO) or indium tin zinc oxide (ITZO), and which is not specifically limited hereto.

Next, forming a planarization layer with a pattern of protrusion by a patterning process using a halftone mask on the substrate on which the functional layer are disposed, and the protrusion is disposed in the region where an opening of a pixel defining layer is to be formed. In the present embodiment, the process of forming the planarization layer with the pattern of protrusion may refer to the previous embodiment.

After that, forming an anode by a patterning process on the substrate on which the planarization layer is disposed. In the present embodiment, the process of forming the anode is may refer to the previous embodiment.

Finally, forming a pixel definition layer by a patterning process on the substrate on which the before-mentioned patterns are formed. In the present embodiment, the process of forming the pixel definition layer may refer to the previous embodiment. In at least some embodiment, the method further comprises a step of forming a spacer on the pixel definition layer.

In at least some embodiment, the process of manufacturing the functional layer may adopt conventional processes, for example, a gate electrode 15 is formed by a first patterning process; a gate insulation layer 14 and an active layer 13 are formed by a second patterning process; a source-drain electrode 17 is formed by a third patterning process. In the present embodiment, the parameters such as material, thickness and the like may refer to those in the previous embodiment.

The embodiment of the present disclosure provides a bottom-gate array substrate, which comprises: a substrate 10; a gate electrode 15 disposed on the substrate 10; a gate insulation layer 14 overlying the gate electrode 15; an active layer 13 disposed on the gate insulation layer 14; a source-drain electrode 17 disposed on the active layer 13; a planarization layer 30 overlying the source-drain electrode 17, wherein a protrusion 31 is disposed on the planarization layer 30 and has a thickness from 1 μm to 3 μm; an anode 40 disposed on the protrusion 31, wherein the anode 40 is connected with a drain of the source-drain electrode 17 through a via hole in the planarization layer; a pixel definition layer 50 disposed on the planarization layer 30, wherein the pixel definition layer 50 is provided with an opening, the protrusion 31 is disposed in a region defined by the opening, the opening is configured to expose the anode 40, an top surface of the pixel definition layer is higher than the top surface of the anode, and a height difference between the top surface of the pixel definition layer and the top surface of the anode ranges from 0.2 μm to 0.4 μm.

In at least some embodiments, the protrusion is formed by a single patterning process using a halftone mask. For example, the spacer is further disposed on the pixel definition layer. The active layer may be a low temperature polysilicon active layer or may be an oxide active layer.

The embodiment of the present disclosure further provides a display panel, which comprises an array substrate described in above embodiments. The display panel may be any product or component with a display function such as a mobile phone, a tablet computer, a television, a monitor, a notebook computer, a digital photo frame and a navigator etc.

The embodiment of the present disclosure further provides a display device, which comprises a display panel described in above embodiments.

An example of the display device is a liquid crystal display device, in which the TFT array substrate and an opposed substrate are disposed opposite to each other so as to form a liquid crystal cell, and a liquid crystal material is filled in the liquid crystal cell. The opposed substrate is, for example, a color filter substrate. A pixel electrode in each pixel unit of the TFT array substrate acts to apply an electric field for controlling the rotation degree of the liquid crystal material, so as to conduct a display operation. In some examples, the liquid crystal display device further comprises a backlight source used to provide backlight for the array substrate.

Another example of the display device is an organic light emitting diode (OLED) display device, in which a pixel electrode in each pixel unit of the TFT array substrate functions as an anode or a cathode for driving an organic light emitting material to emit light, so as to conduct a display operation.

Still another example of the display device is an electronic paper display device, an electronic ink layer is formed on an array substrate, a pixel electrode in each pixel unit is configured to apply a voltage for driving charged micro particles in the electronic ink to move, so as to conduct a display operation.

In the present disclosure, the following points needs to explain:

(1) The accompanying drawings involve only the structure(s) in connection with the embodiment(s) of the present disclosure, and other structure(s) can be referred to common design(s).

(2) For the purpose of clarity only, in accompanying drawings for illustrating the embodiment(s) of the present disclosure, the thickness and a size of a layer or area may be enlarged or narrowed, that is, the drawings are not drawn in a real scale.

(3) In case of no conflict, features in one embodiment or in different embodiments can be combined as a new embodiment.

1. An array substrate, comprising:
a substrate; and
a planarization layer and a pixel definition layer sequentially disposed on the substrate, wherein a protrusion is disposed on the planarization layer, the pixel definition layer is provided with an opening, and the protrusion is disposed in a region defined by the opening.

2. The array substrate according to claim 1, further comprising an anode, wherein the anode is disposed on the protrusion.

3. The array substrate according to claim 1, further comprising a spacer, wherein the spacer is disposed on the pixel definition layer.

4. The array substrate according to claim 1, wherein a top surface of the pixel definition layer is higher than a top surface of the protrusion, relative to a plane of the substrate.

5. The array substrate according to claim 1, wherein a thickness of the protrusion ranges from 1 μm to 3 μm, and a thickness of the pixel definition layer ranges from 1.4 μm to 3.6 μm.

6. The array substrate according to claim 2, wherein a top surface of the pixel definition layer is higher than a top surface of the anode, relative to the plane of the substrate.

7. The array substrate according to claim 6, wherein a height difference between the top surface of the pixel definition layer and the top surface of the anode ranges from 0.2 μm to 0.4 μm.

8. A method for manufacturing an array substrate, comprising:
forming a planarization layer on which a protrusion is disposed; and
forming a pixel definition layer, wherein the pixel definition layer is provided with an opening, and the protrusion is disposed in a region defined by the opening.

9. The method for manufacturing the array substrate according to claim 8, further comprising: forming an anode on the protrusion.

10. The method for manufacturing the array substrate according to claim 8, further comprising: forming a spacer on the pixel definition layer.

11. The method for manufacturing the array substrate according to claim 8, wherein both the planarization layer and the pixel definition layer are formed on the substrate, and a top surface of the pixel definition layer is higher than a top surface of the protrusion, relative to a plane of the substrate.

12. The method for manufacturing the array substrate according to claim 8, wherein a thickness of the protrusion ranges from 1 μm to 3 μm, and a thickness of the pixel definition layer ranges from 1.4 μm to 3.6 μm.

13. The method for manufacturing the array substrate according to claim 9, wherein both the planarization layer and the pixel definition layer are formed on the substrate, and a top surface of the pixel definition layer is higher than a top surface of the anode, relative to the plane of the substrate.

14. The method for manufacturing the array substrate according to claim 13, wherein a height difference between the top surface of the pixel definition layer and the top surface of the anode ranges from 0.2 μm to 0.4 μm.

15. The method for manufacturing the array substrate according to claim 8, wherein the forming a planarization layer on which a protrusion is disposed comprises:
forming a planarization film; and
exposing the planarization film with a dual-tone or halftone mask and developing, wherein a region of the planarization film where a via hole is to be formed in the planarization layer is a full exposure region; a region where an opening is to be formed is an non-exposure region, and the protrusion is formed in non-exposure region; the remaining region is a partial exposure region, in which the planarization layer is to be formed.

16. The method for manufacturing the array substrate according to claim 8, wherein the planarization layer and the protrusion are made of a photosensitive material.

17. A display panel, comprising: the array substrate according to claim 1.

18. A display device, comprising: the display panel according to claim 17.

19. The array substrate according to claim 1, wherein the protrusion and the planarization layer are made from same planarization film, the same planarization film comprises a first part which is in the region defined by the opening and a second part which is outside the region defined by the opening, a thickness of the first part being larger than a thickness of the second part.

20. The array substrate according to claim 2, further comprising a thin film transistor and a via hole, wherein the via hole is configured for electrically connecting the thin film transistor and the anode, and an orthographical projection of the via hole on the substrate is in non-overlap with an orthographical projection of the protrusion on the substrate.
